(19) United States
(12) Patent Application Publication
(10) Pub. No.: US 2013/0222077 A1
(43) Pub. Date: Aug. 29, 2013

(54) ELASTIC WAVE FILTER DEVICE

(71) Applicant: Murata Manufacturing Co., Ltd., (US)

(72) Inventor: Noriyoshi OTA, Nagaokakyo-shi (JP)

(73) Assignee: Murata Manufacturing Co., Ltd., Nagaokakyo-shi (JP)

(21) Appl. No.: 13/854,284

(22) Filed: Apr. 1, 2013

Related U.S. Application Data
(63) Continuation of application No. PCT/JP2011/065550, filed on Jul. 7, 2011.

(30) Foreign Application Priority Data
Oct. 6, 2010 (JP) 2010-226493

(51) Int. Cl. H03H 9/70; H03H 9/64; H03H 9/58; H03H 9/72

(52) U.S. Cl. CPC H03H 9/64
USPC 333/133; 333/189; 333/195

(57) ABSTRACT

An elastic wave filter device includes first and second signal terminals, an inductor, and a ladder elastic wave filter unit. The elastic wave filter device includes an elastic wave filter chip provided with the ladder elastic wave filter unit and a wiring board. The wiring board includes a plurality of dielectric layers and a plurality of electrode layers alternately laminated. An inductor electrode and a ground electrode are arranged so as to not face each other via the dielectric layer.

### BACKGROUND OF THE INVENTION

1. Field of the Invention

The present invention relates to an elastic wave filter device.

2. Description of the Related Art

In the past, a variety of surface acoustic wave filter devices using surface acoustic waves have been proposed in, for example, the Japanese Unexamined Patent Application Publication No. 2010-11300 as a band pass filter and a branching filter mounted on or in an RF (Radio Frequency) circuit of a communication device, such as a cellular phone.

FIG. 20 is a schematic circuit diagram of a surface acoustic wave branching filter corresponding to a surface acoustic wave filter device described in Japanese Unexamined Patent Application Publication No. 2010-11300. As illustrated in FIG. 20, a surface acoustic wave branching filter 100 includes an antenna terminal 101, a transmitting terminal 102, and first and second receiving terminals 103a and 103b. A transmission filter 110 is connected between the antenna terminal 101 and the transmitting terminal 102. A reception filter 120 is connected between the antenna terminal 101 and the first and second receiving terminals 103a and 103b.

The transmission filter 110 is provided by a ladder surface acoustic wave filter. The transmission filter 110 includes a series arm 111 for connecting the antenna terminal 101 and the transmitting terminal 102. The series arm 111 is disposed with series arm resonators S101 to S104. Each of the series arm resonators S101 to S104 is formed by a plurality of surface acoustic wave resonators. A capacitor C101 is connected in parallel with two surface acoustic wave resonators forming the series arm resonator S102. A capacitor C102 and an inductor L101 are connected in parallel with a surface acoustic wave resonator forming the series arm resonator S104. Parallel arms 112a, 112b, and 112c are connected between the series arm 111 and the ground. The parallel arms 112a to 112c are disposed with parallel arm resonators P101 to P103, respectively. Each of the parallel arm resonators P101 to P103 is formed by a plurality of surface acoustic wave resonators. In the parallel arm 112a, an inductor L103 is connected between the parallel arm resonator P101 and the ground. In the parallel arm 112b, an inductor L104 is connected between the parallel arm resonator P102 and the ground. In the parallel arm 112c, an inductor L105 is connected between the parallel arm resonator P103 and the ground. An inductor L106 is connected between the inductors L103 and L104 and the ground.

In general, an elastic wave filter device, such as the surface acoustic wave branching filter 100, is provided by an elastic wave filter chip and a wiring board. The elastic wave filter chip includes a piezoelectric substrate and electrodes formed on the piezoelectric substrate. The wiring board includes a plurality of dielectric layers and a plurality of electrode layers, and the dielectric layers and the electrode layers are alternately laminated with one another. The elastic wave filter chip is mounted on the wiring board.

In an elastic wave filter device including an inductor, such as the surface acoustic wave branching filter 100, the inductor is formed by electrodes of electrode layers forming the wiring board. Therefore, there is a problem in that, in the manufacture of the elastic wave filter device, manufacturing variations of the wiring board occasionally cause variations in inductance value of the inductor and thus also cause variations in filter characteristic of the manufactured elastic wave filter device.

### SUMMARY OF THE INVENTION

Preferred embodiments of the present invention provide an elastic wave filter device having small manufacturing variations in filter characteristics.

An elastic wave filter device according to a preferred embodiment of the present invention includes first and second signal terminals, an inductor, and a ladder elastic wave filter unit. The ladder elastic wave filter unit is connected between the first signal terminal and the second signal terminal. The elastic wave filter device according to a preferred embodiment of the present invention includes an elastic wave filter chip and a wiring board. The elastic wave filter chip is provided with the ladder elastic wave filter unit. The wiring board includes first and second main surfaces. The elastic wave filter chip is mounted on the first main surface of the wiring board. The wiring board includes a plurality of dielectric layers and a plurality of electrode layers alternately laminated with one another. In the plurality of electrode layers, an electrode layer defining an uppermost layer includes a land electrode connected to the elastic wave filter chip. In the plurality of electrode layers, an electrode layer defining a lowermost layer includes a terminal providing the first signal terminal and a terminal providing the second signal terminal. In the plurality of electrode layers, at least one electrode layer includes an inductor electrode defining the inductor. In the plurality of electrode layers, an electrode layer disposed adjacent, via a dielectric layer of the plurality of dielectric layers, to the electrode layer including the inductor electrode includes a ground electrode connected to the ground. The inductor electrode and the ground electrode are arranged so as to not face each other via the dielectric layer.

In a specific aspect of the elastic wave filter device according to a preferred embodiment of the present invention, the inductor is connected in series between the first signal terminal and the second signal terminal.

In a preferred embodiment of the present invention, the inductor electrode and the ground electrode are arranged so as to not face each other via the dielectric layer. It is therefore possible to reduce the manufacturing variations in filter characteristic of the elastic wave filter device.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic circuit diagram of a duplexer according to a preferred embodiment of the present invention.

FIG. 2 is a schematic cross-sectional view of the duplexer according to a preferred embodiment of the present invention.

FIG. 3 is a schematic perspective plan view of a fourth electrode layer and a third dielectric layer of a wiring board in the duplexer according to a preferred embodiment of the present invention.

FIG. 4 is a schematic perspective plan view of a third electrode layer and a second dielectric layer of the wiring board in the duplexer according to a preferred embodiment of the present invention.

FIG. 5 is a schematic perspective plan view of a second electrode layer and a first dielectric layer of the wiring board in the duplexer according to a preferred embodiment of the present invention.

FIG. 6 is a schematic perspective plan view of a first electrode layer of the wiring board in the duplexer according to a preferred embodiment of the present invention.

FIG. 7 is a schematic perspective plan view illustrating an overlapping state of the first electrode layer and the second electrode layer of the wiring board in the duplexer according to a preferred embodiment of the present invention.

FIG. 8 is a schematic perspective plan view illustrating an overlapping state of a first electrode layer and a second electrode layer of a wiring board in a duplexer according to a comparative example.

FIG. 9 is a schematic perspective plan view of a fourth electrode layer and a third dielectric layer of the wiring board in the duplexer according to the comparative example.

FIG. 10 is a schematic perspective plan view of a third electrode layer and a second dielectric layer of the wiring board in the duplexer according to the comparative example.

FIG. 11 is a schematic perspective plan view of the second electrode layer and a first dielectric layer of the wiring board in the duplexer according to the comparative example.

FIG. 12 is a schematic perspective plan view of the first electrode layer of the wiring board in the duplexer according to the comparative example.

FIG. 13 includes graphs illustrating filter characteristics of a transmission filter of a duplexer according to an example of a preferred embodiment of the present invention.

FIG. 14 includes Smith charts at a transmitting terminal of the duplexer according to the example of a preferred embodiment of the present invention.

FIG. 15 includes graphs illustrating VSWR (Voltage Standing Wave Ratio) characteristics of the transmission filter of the duplexer according to the example of a preferred embodiment of the present invention.

FIG. 16 includes graphs illustrating filter characteristics of a transmission filter of the duplexer according to the comparative example.

FIG. 17 includes Smith charts at a transmitting terminal of the duplexer according to the comparative example.

FIG. 18 includes graphs illustrating VSWR characteristics of the transmission filter of the duplexer according to the comparative example.

FIG. 19 includes graphs illustrating a filter characteristic of the transmission filter of the duplexer according to the example of a preferred embodiment of the present invention and a filter characteristic of the transmission filter of the duplexer according to the comparative example in a case where the thickness of the first dielectric layer is about 25 μm.

FIG. 20 is a schematic circuit diagram of a surface acoustic wave branching filter described in Japanese Unexamined Patent Application Publication No. 2010-11300.

### DETAILED DESCRIPTION OF THE PREFERRED EMBODIMENTS

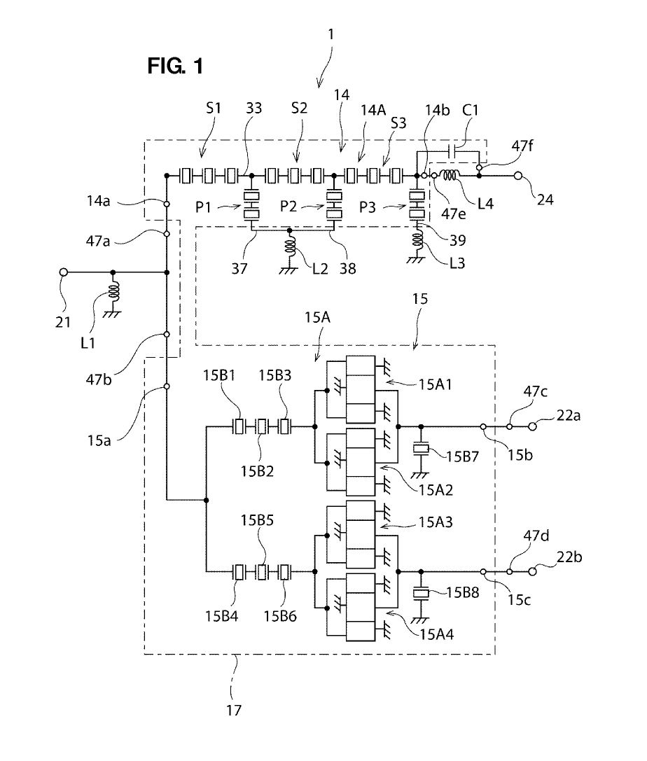

Preferred embodiments of the present invention will be described below with reference to, as an example, a duplexer 1 illustrated in FIG. 1. The duplexer 1, however, is merely an exemplification. An elastic wave filter device according to the present invention is not limited to the duplexer 1 illustrated in FIG. 1.

In various preferred embodiments of the present invention, an elastic wave filter device is assumed to include an elastic wave branching filter, such as, for example, an elastic wave duplexer and an elastic wave triplexer, which includes a plurality of elastic wave filter units.

Further, an “elastic wave” is assumed to include both a surface acoustic wave and a boundary acoustic wave. That is, an elastic wave filter is assumed to include both a surface acoustic wave filter and a boundary acoustic wave filter.

FIG. 1 is a schematic circuit diagram of the duplexer 1 according to the present preferred embodiment. With reference to FIG. 1, a circuit configuration of the duplexer 1 will first be described.

The duplexer 1 of the present preferred embodiment is preferably mounted on or in, for example, an RF circuit of a cellular phone or the like supporting a CDMA system, such as UMTS, for example. Specifically, the duplexer 1 is preferably a duplexer supporting UMTS-BAND2. The transmission frequency band of UMTS-BAND2 is about 1850 MHz to about 1910 MHz, and the reception frequency band of UMTS-BAND2 is about 1930 MHz to about 1990 MHz.

The duplexer 1 preferably includes an antenna terminal 21 connected to an antenna, a transmitting terminal 24, and first and second receiving terminals 22a and 22b. A transmission filter 14 is preferably connected between the antenna terminal 21 and the transmitting terminal 24. Further, a reception filter 15 preferably is connected between the antenna terminal 21 and the first and second receiving terminals 22a and 22b. A matching circuit including an inductor L1 is preferably connected between a connection point of the antenna terminal 21, the transmission filter 14, and the reception filter 15 and the ground.

In the present preferred embodiment, the reception filter 15 preferably includes an unbalanced signal terminal 15a and first and second balanced signal terminals 15b and 15c. The unbalanced signal terminal 15a is connected to the antenna terminal 21. The first balanced signal terminal 15b is connected to the first receiving terminal 22a. The second balanced signal terminal 15c is connected to the second receiving terminal 22b.

A balanced longitudinally coupled resonator-type elastic wave filter unit 15A possessing a balanced-unbalanced transforming function is preferably connected between the unbalanced signal terminal 15a and the first and second balanced signal terminals 15b and 15c.

The longitudinally coupled resonator-type elastic wave filter unit 15A preferably includes a first longitudinally coupled resonator-type elastic wave filter unit 15A1, a second longitudinally coupled resonator-type elastic wave filter unit 15A2, a third longitudinally coupled resonator-type elastic wave filter unit 15A3, a fourth longitudinally coupled resonator-type elastic wave filter unit 15A4, and elastic wave resonators 15B1 to 15B8.

Each of the first to fourth longitudinally coupled resonator-type elastic wave filter units 15A1 to 15A4 preferably includes three IDT electrodes and reflectors disposed on the opposite sides of the IDT electrodes in a propagation direction of the elastic wave. That is, each of the first to fourth longitudinally coupled resonator-type elastic wave filter units 15A1 to 15A4 is, for example, a 3-IDT longitudinally coupled resonator-type elastic wave filter unit.

Each of the elastic wave resonators 15B1 to 15B8 preferably includes one IDT electrode and reflectors disposed on the opposite sides of the IDT electrode in the propagation direction of the elastic wave. That is, each of the elastic wave resonators 15B1 to 15B8 is, for example, a 1-port elastic wave resonator.

Meanwhile, the transmission filter 14 preferably includes an output terminal 14a, an input terminal 14b, and a ladder elastic wave filter unit 14A. The output terminal 14a is connected to the antenna terminal 21. The input terminal 14b is connected to the transmitting terminal 24. The ladder elastic wave filter unit 14A is connected between the output terminal 14a and the input terminal 14b.

The ladder elastic wave filter unit 14A preferably includes a series arm 33 connecting the output terminal 14a and the input terminal 14b. In the series arm 33, series arm resonators S1, S2, and S3 are preferably connected in series. Each of the series arm resonators S1, S2, and S3 preferably includes a plurality of elastic wave resonators functioning as one resonator. With each of the series arm resonators S1, S2, and S3 including a plurality of elastic wave resonators, it is possible to enhance the electric power handling capability of the ladder elastic wave filter unit 14A. Each of the series arm resonators S1, S2, and S3, however, may be provided by a single elastic wave resonator, if so desired.

The ladder elastic wave filter unit 14A includes parallel arms 37, 38, and 39 connected between the series arm 33 and the ground. The parallel arms 37, 38, and 39 are provided with parallel arm resonators P1, P2, and P3, respectively. Each of the parallel arm resonators P1, P2, and P3 is preferably defined by a plurality of elastic wave resonators functioning as one resonator. With each of the parallel arm resonators P1, P2, and P3 thus defined by a plurality of elastic wave resonators, it is possible to enhance the electric power handling capability of the ladder elastic wave filter unit 14A. Each of the parallel arm resonators P1, P2, and P3, however, may alternatively be defined by a single elastic wave resonator.

An inductor L2 is preferably connected between the parallel arm resonators P1 and P2 and the ground. More specifically, the inductor L2 is connected between the ground and a common connection point to which the parallel arm resonators P1 and P2 are connected. With the provision of the inductor L2, an attenuation pole is defined on the lower side of the pass band of the transmission filter 14. With this attenuation pole, a signal in the GPS band (about 1574.42 MHz to about 1576.42 MHz) is attenuated.

Meanwhile, an inductor L3 is preferably connected between the parallel arm resonator P3 and the ground. With the provision of the inductor L3, an attenuation pole is defined on the higher side of the pass band of the transmission filter 14. With this attenuation pole, a third harmonic signal is attenuated.

The transmission filter 14 preferably includes an LC resonant circuit defined by a capacitor C1 and an inductor L4. The capacitor C1 and the inductor L4 are preferably connected in series between the input terminal 14b and the transmitting terminal 24. Further, the capacitor C1 and the inductor L4 are connected in parallel to each other. With this LC resonant circuit, an attenuation pole is defined on the higher side of the pass band of the transmission filter 14. With this attenuation pole, a second harmonic signal is attenuated. Further, with the capacitor C1 and the inductor L4, the impedance at the transmitting terminal 24 is matched.

Each of the elastic wave resonators defining the series arm resonators S1 to S3 and the parallel arm resonators P1 to P3 preferably includes one IDT electrode and one pair of reflectors disposed on the opposite sides of the IDT electrode in the propagation direction of the elastic wave. That is, each of the elastic wave resonators defining the series arm resonators S1 to S3 and the parallel arm resonators P1 to P3 is, for example, a 1-port elastic wave resonator. The capacitor C1 is preferably provided by a pair of mutually interposed comb-shaped electrodes.

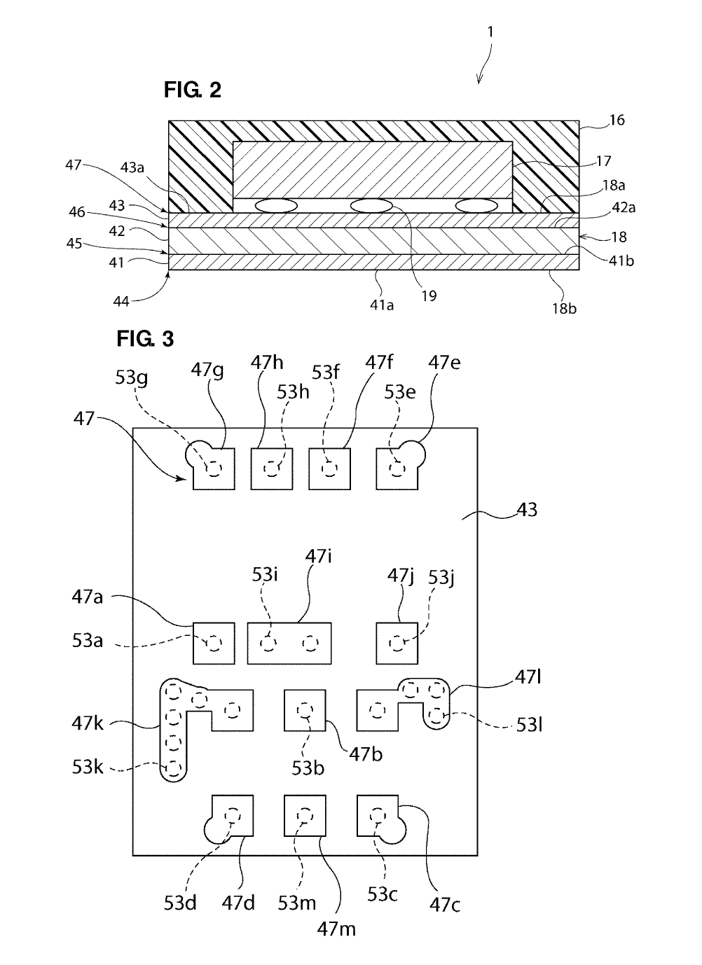

FIG. 2 is a schematic cross-sectional view of the duplexer 1 according to the present preferred embodiment. Subsequently, a specific configuration of the duplexer 1 of the present preferred embodiment will be described with reference to FIG. 2.

The duplexer 1 preferably includes an elastic wave filter chip 17 and a wiring board 18. The wiring board 18 includes first and second main surfaces 18a and 18b, and the elastic wave filter chip 17 is preferably flip-chip mounted on the first main surface 18a by bumps 19, for example. That is, the first main surface 18a is a die-attach surface. The elastic wave filter chip 17 is preferably sealed by a sealing resin 16 provided on the first main surface 18a. That is, the duplexer 1 of the present preferred embodiment is a CSP (Chip Size Package) elastic wave branching filter.

In the present preferred embodiment, the elastic wave filter chip 17 corresponds to a portion of the above-described transmission filter 14 excluding the inductors L2, L3, and L4 and the reception filter 15, which are preferably integrally formed. In the present invention, however, a transmission-side elastic wave filter chip provided with the portion of the transmission filter 14 excluding the inductors L2, L3, and L4 and a reception-side elastic wave filter chip provided with the reception filter 15 may be separately provided.

The elastic wave filter chip 17 preferably includes a piezoelectric substrate and electrodes including IDT electrodes, reflectors, wiring lines, and so forth formed on the piezoelectric substrate. The elastic wave filter chip 17 may further include one or a plurality of dielectric layers arranged on the piezoelectric substrate to cover the IDT electrodes.

The piezoelectric substrate may be provided by, for example, a LiTaO₃ substrate or a LiNbO₃ substrate. Further, the electrodes may be made of, for example, a metal such as Al, an alloy of Al, etc. The electrodes may also be defined by, for example, a laminate of a plurality of metal layers.

The wiring board 18 is preferably a laminate including first to third dielectric layers 41 to 43 and first to fourth electrode layers 44 to 47. The first electrode layer 44 is disposed under the first dielectric layer 41. The second electrode layer 45 is disposed between the first dielectric layer 41 and the second dielectric layer 42. The third electrode layer 46 is disposed between the second dielectric layer 42 and the third dielectric layer 43. The fourth electrode layer 47 is disposed on the third dielectric layer 43. The first dielectric layer 41 and the first electrode layer 44 define the second main surface 18b. Meanwhile, the first main surface 18a is provided as a die-attach surface by the third dielectric layer 43 and the fourth electrode layer 47, for example.

Each of the first to third dielectric layers 41 to 43 may be made of, for example, a resin or ceramics such as alumina. That is, the wiring board 18 may be a multilayer printed wiring board made of a resin or a multilayer ceramic board, for example.

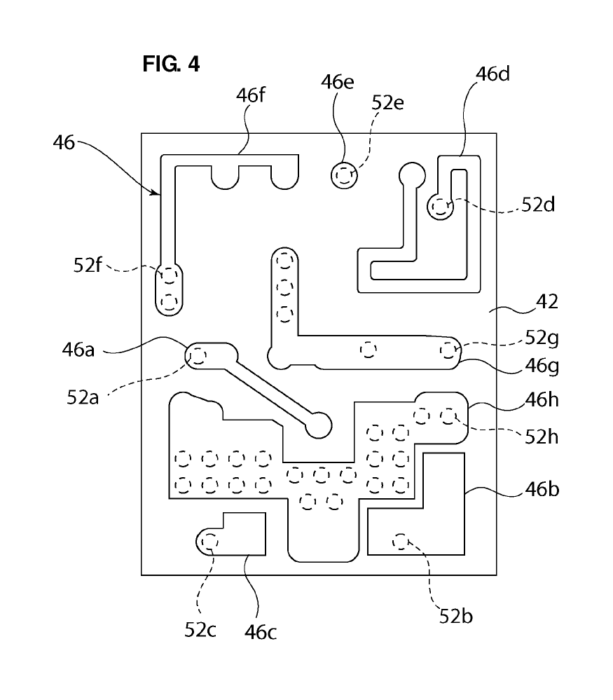

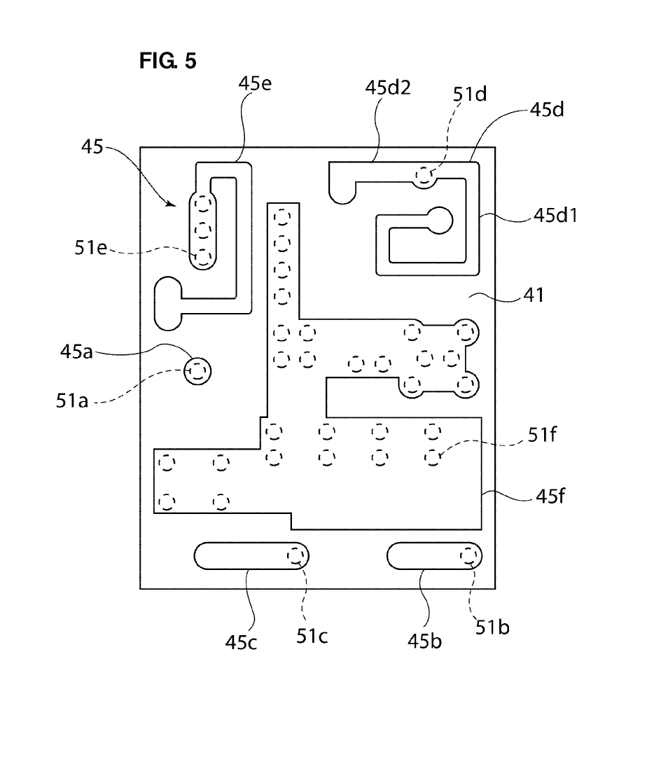

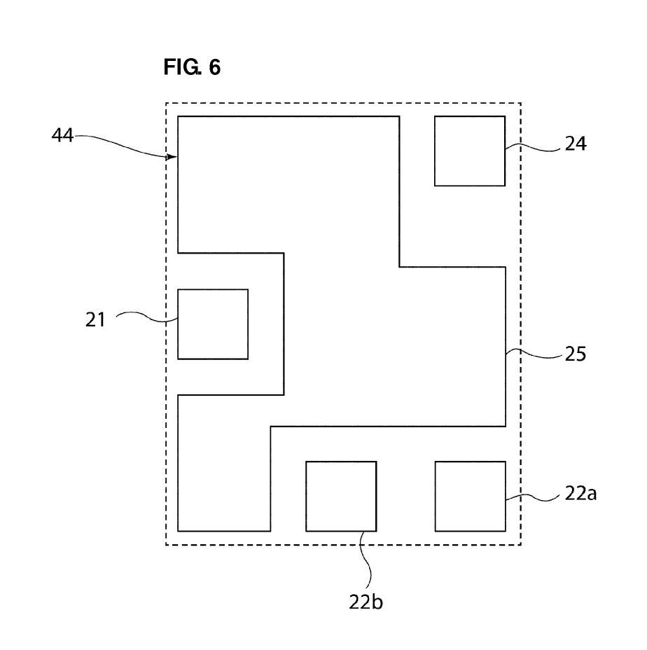

FIG. 3 is a schematic perspective plan view of the fourth electrode layer 47 and the third dielectric layer 43 of the wiring board 18 in the duplexer 1 according to the present preferred embodiment. FIG. 4 is a schematic perspective plan view of the third electrode layer 46 and the second dielectric layer 42 of the wiring board 18 in the duplexer 1 according to the present preferred embodiment. FIG. 5 is a schematic perspective plan view of the second electrode layer 45 and the first dielectric layer 41 of the wiring board 18 in the duplexer 1 according to the present preferred embodiment. FIG. 6 is a schematic perspective plan view of the first electrode layer 44 of the wiring board 18 in the duplexer 1 according to the present preferred embodiment.

As illustrated in FIG. 3, the fourth electrode layer 47 is preferably defined by land electrodes 47a to 47m. The fourth electrode layer 47 is a land electrode layer. As illustrated in FIG. 4, the third electrode layer 46 is preferably defined by electrodes 46a to 46h. The third electrode layer 46 is an intermediate electrode layer. As illustrated in FIG. 5, the second electrode layer 45 is preferably defined by electrodes 45a to 45f. The second electrode layer 45 is an intermediate electrode layer. As illustrated in FIG. 6, the first electrode layer 44 is preferably defined by the antenna terminal 21, the first and second receiving terminals 22a and 22b, the transmitting terminal 24, and a ground terminal 25. The first electrode layer 44 is a rear surface terminal layer.

The antenna terminal 21 of the first electrode layer 44 is preferably connected to the electrode 45a of the second electrode layer 45 by a via hole electrode 51a of the first dielectric layer 41. The electrode 45a of the second electrode layer 45 is preferably connected to the electrode 46a of the third electrode layer 46 by a via hole electrode 52a of the second dielectric layer 42. The electrode 46a of the third electrode layer 46 is preferably connected to the land electrodes 47a and 47b of the fourth electrode layer 47 by via hole electrodes 53a and 53b of the third dielectric layer 43. The land electrode 47a of the fourth electrode layer 47 is preferably connected to the output terminal 14a of the elastic wave filter chip 17 by, for example, bump-bonding. The land electrode 47b of the fourth electrode layer 47 is preferably connected to the unbalanced signal terminal 15a of the elastic wave filter chip 17 by, for example, bump-bonding.

The first receiving terminal 22a of the first electrode layer 44 is preferably connected to the electrode 45b of the second electrode layer 45 by a via hole electrode 51b of the first dielectric layer 41. The electrode 45b of the second electrode layer 45 is preferably connected to the electrode 46b of the third electrode layer 46 by a via hole electrode 52b of the second dielectric layer 42. The electrode 46b of the third electrode layer 46 is preferably connected to the land electrode 47c of the fourth electrode layer 47 by a via hole electrode 53c of the third dielectric layer 43. The land electrode 47c of the fourth electrode layer 47 is preferably connected to the first balanced signal terminal 15b of the elastic wave filter chip 17 by, for example, bump-bonding.

The second receiving terminal 22b of the first electrode layer 44 is preferably connected to the electrode 45c of the second electrode layer 45 by a via hole electrode 51c of the first dielectric layer 41. The electrode 45c of the second electrode layer 45 is preferably connected to the electrode 46c of the third electrode layer 46 by a via hole electrode 52c of the second dielectric layer 42. The electrode 46c of the third electrode layer 46 is preferably connected to the land electrode 47d of the fourth electrode layer 47 by a via hole electrode 53d of the third dielectric layer 43. The land electrode 47d of the fourth electrode layer 47 is preferably connected to the second balanced signal terminal 15c of the elastic wave filter chip 17 by, for example, bump-bonding.

The transmitting terminal 24 of the first electrode layer 44 is preferably connected to the electrode 45d of the second electrode layer 45 by a via hole electrode 51d of the first dielectric layer 41. The electrode 45d of the second electrode layer 45 preferably includes electrode portions 45d1 and 45d2. The electrode portion 45d1 is a portion extending from one end portion of the electrode 45d of the second electrode layer 45 to a connection point connected to the via hole electrode 51d of the first dielectric layer 41. The electrode portion 45d2 is a portion extending from the other end portion of the electrode 45d of the second electrode layer 45 to a connection point connected to the via hole electrode 51d of the first dielectric layer 41. The electrode portion 45d1 defines the inductor L4. The electrode 45d of the second electrode layer 45 is preferably connected to the electrodes 46d and 46e of the third electrode layer 46 by via hole electrodes 52d and 52e of the second dielectric layer 42. The electrode 46d of the third electrode layer 46 defines the inductor L4. The electrode 46d of the third electrode layer 46 is preferably connected to the land electrode 47e of the fourth electrode layer 47 by a via hole electrode 53e of the third dielectric layer 43. The land electrode 47e of the fourth electrode layer 47 is preferably connected to the input terminal 14b of the elastic wave filter chip 17 by, for example, bump-bonding. The electrode 46e of the third electrode layer 46 is preferably connected to the land electrode 47f of the fourth electrode layer 47 by a via hole electrode 53f of the third dielectric layer 43. The land electrode 47f of the fourth electrode layer 47 is preferably connected to the capacitor C1 of the elastic wave filter chip 17 by, for example, bump-bonding.

The ground terminal 25 of the first electrode layer 44 is preferably connected to the electrodes 45e and 45f of the second electrode layer 45 by via hole electrodes 51e and 51f of the first dielectric layer 41. The electrode 45e of the second electrode layer 45 defines the inductor L2. The electrode 45e of the second electrode layer 45 is preferably connected to the electrode 46f of the third electrode layer 46 by a via hole electrode 52f of the second dielectric layer 42. The electrode 46f of the third electrode layer 46 defines the inductor L2. The electrode 45f of the second electrode layer 45 is preferably connected to the electrodes 46g and 46h of the third electrode layer by via hole electrodes 52g and 52h of the second dielectric layer 42. The electrode 46g of the third electrode layer 46 defines the inductor L3. The electrode 46f of the third electrode layer 46 is preferably connected to the land electrodes 47g and 47h of the fourth electrode layer 47 by via hole electrodes 53g and 53h of the third dielectric layer 43. The electrode 46g of the third electrode layer 46 is preferably connected to the land electrodes 47i and 47j of the fourth electrode layer 47 by via hole electrodes 53i and 53j of the third dielectric layer 43. The electrode 46h of the third electrode layer 46 is preferably connected to the land electrodes 47k, 47l, and 47m of the fourth electrode layer 47 by via hole electrodes 53k, 53l, and 53m of the third dielectric layer 43. The land electrode 47g of the fourth electrode layer 47 is connected to the parallel arm resonator P1 of the elastic wave filter chip 17 by, for example, bump-bonding. The land electrode 47h of the fourth electrode layer 47 is connected to the parallel arm resonator P2 of the elastic wave filter chip 17 by, for example, bump-bonding. The land electrode 47i of the fourth electrode layer 47 is connected to a dummy electrode of the elastic wave filter chip 17 by, for example, bump-bonding. The land electrode 47j of the fourth electrode layer 47 is connected to the parallel arm resonator P3 of the elastic wave filter chip 17 by, for example, bump-bonding. The land electrodes 47k, 47l, and 47m of the fourth electrode layer 47 are connected to the first to fourth longitudinally coupled resonator-type elastic wave filter units 15A1 to 15A4 of the elastic wave filter chip 17 by, for example, bump-bonding. The ground terminal 25 of the first electrode layer 44, the electrode 45f of the second electrode layer 45, and the electrode 46h of the third electrode layer 46 are ground electrodes arranged to connect the transmission filter 14 and the reception filter 15 to the ground.

As described above, in the present preferred embodiment, a portion of the electrode 45d (electrode portion 45d1) of the second electrode layer 45 and the electrode 46d of the third electrode layer 46 define the inductor L4. That is, a portion of the electrode 45d (electrode portion 45d1) of the second electrode layer 45 and the electrode 46d of the third electrode layer 46 are inductor electrodes defining the inductor L4.

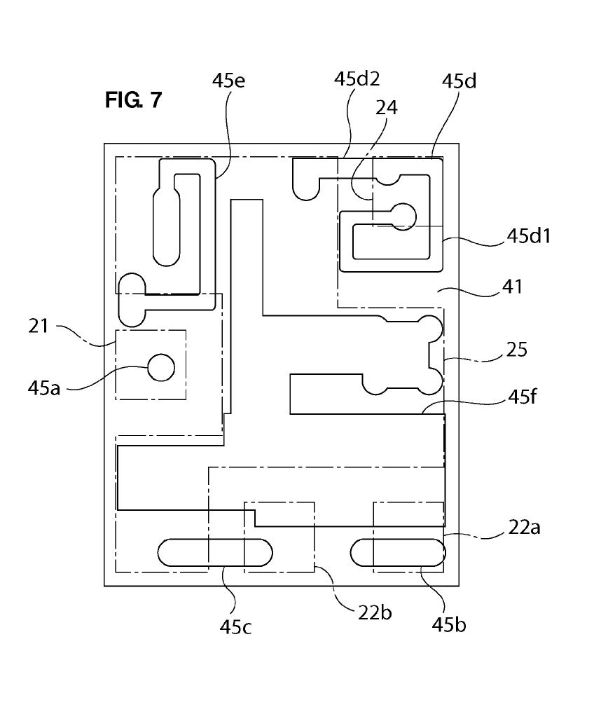

FIG. 7 is a schematic perspective plan view illustrating an overlapping state of the first electrode layer 44 and the second electrode layer 45 of the wiring board 18 in the duplexer 1 according to the present preferred embodiment. In FIG. 7, the second electrode layer 45 is indicated by solid lines, and the first electrode layer 44 is indicated by dash-dotted lines.

As illustrated in FIG. 7, in the duplexer 1 of the present preferred embodiment, the ground terminal 25 of the first electrode layer 44 and a portion of the electrode 45d (electrode portion 45d1) of the second electrode layer 45 defining the inductor L4 preferably do not overlap each other, as viewed from above. That is, the ground terminal 25 of the first electrode layer 44 and a portion of the electrode 45d (electrode portion 45d1) of the second electrode layer 45 do not face each other via the first dielectric layer 41.

Meanwhile, if a ground electrode connected to the ground, such as, for example, the ground terminal 25, and an inductor electrode defining an inductor, such as, for example, the electrode 45d, face each other via a dielectric layer in the wiring board 18, a capacitance is produced between the two mutually facing electrodes. Herein, there actually arise variations in thickness of the first to third dielectric layers 41 to 43 in the production of the wiring board 18. Therefore, the magnitude of the capacitance produced between the two mutually facing electrodes varies, and thereby the inductance value of the inductor also varies. As a result, there arise variations also in filter characteristic of the filter including the inductor.

Meanwhile, in the present preferred embodiment, the ground terminal 25 of the first electrode layer 44 and a portion of the electrode 45d (electrode portion 45d1) of the second electrode layer 45 preferably do not face each other via the first dielectric layer 41, as described above. Therefore, the magnitude of the capacitance produced between the ground terminal 25 of the first electrode layer 44 and a portion of the electrode 45d (electrode portion 45d1) of the second electrode layer 45 is very small. Even if variations in thickness of the first dielectric layer 41 occur, the magnitude of the capacitance only barely changes, and the filter characteristics of the transmission filter 14 including the inductor L4 barely varies. In the duplexer 1 of the present preferred embodiment, therefore, it is possible to reduce the manufacturing variations of the filter characteristics.

The inductor L4 is connected in series with the transmitting terminal 24. Therefore, the filter characteristic of the transmission filter 14 is greatly affected by a change in characteristics of the inductor L4 caused by a change in magnitude of the capacitance produced between the ground terminal 25 of the first electrode layer 44 and a portion of the electrode 45d (electrode portion 45d1) of the second electrode layer 45. Further, as well as the capacitor C1, the inductor L4 has a function of matching the impedance at the transmitting terminal 24. Therefore, the matching state of the impedance at the transmitting terminal 24 is also greatly affected by a change in characteristics of the inductor L4 caused by a change in a magnitude of the capacitance produced between the ground terminal 25 of the first electrode layer 44 and a portion of the electrode 45d (electrode portion 45d1) of the second electrode layer 45. In an inductor connected in series between an antenna terminal and a transmitting terminal, therefore, it is particularly important to dispose an inductor electrode defining the inductor such that the inductor electrode does not face, via a dielectric layer, a ground electrode connected to the ground.

Further, in the duplexer 1 of the present preferred embodiment, due to the small magnitude of the capacitance produced between the ground terminal 25 of the first electrode layer 44 and a portion of the electrode 45d (electrode portion 45d1) of the second electrode layer 45, the Q value of the inductor L4 is increased. Herein, the inductor L4 is connected in series with a signal line of the transmission filter 14. Thus, the resistance component of the inductor L4 is reduced, and the loss in the inductor L4 is reduced. It is therefore possible to reduce the insertion loss in the pass band of the transmission filter 14.

In the above-described preferred embodiment, description has been made of the positional relationship between the ground terminal 25 of the first electrode layer 44 and a portion of the electrode 45d (electrode portion 45d1) of the second electrode layer 45. In the present invention, however, the electrode layer including the inductor electrode defining the inductor and the electrode layer including the ground electrode connected to the ground may be any electrode layers, as long as the electrode layers are disposed adjacent to each other via a dielectric layer.

Effects of the above-described present preferred embodiment will be described in detail below on the basis of a specific non-limiting example of a preferred embodiment of the present invention and a comparative example.

Firstly, as a non-limiting example preferred embodiment of the present invention, the duplexer 1 of the above-described preferred embodiment was produced.

Further, as a comparative example, a duplexer was produced which is similar in configuration to the above-described preferred embodiment example except that the respective shapes of the ground terminal 25 of the first electrode layer 44, the electrode 45d of the second electrode layer 45, and the electrodes 46d and 46e of the third electrode layer 46 in the wiring board 18 are different from those of the duplexer 1.

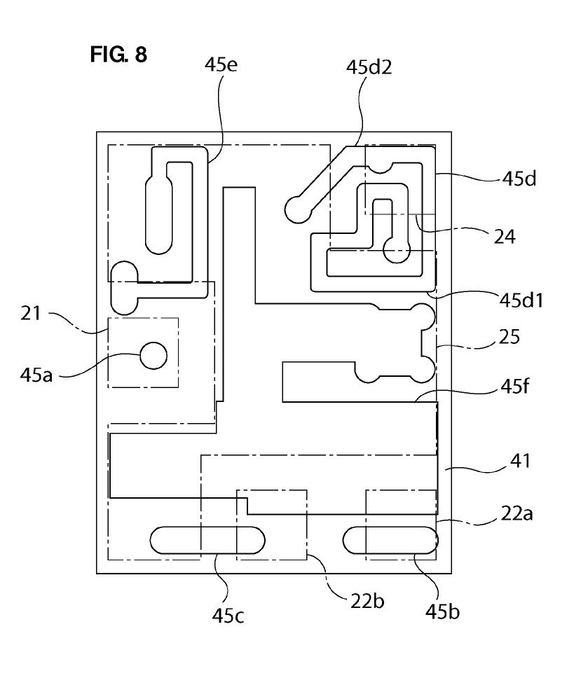

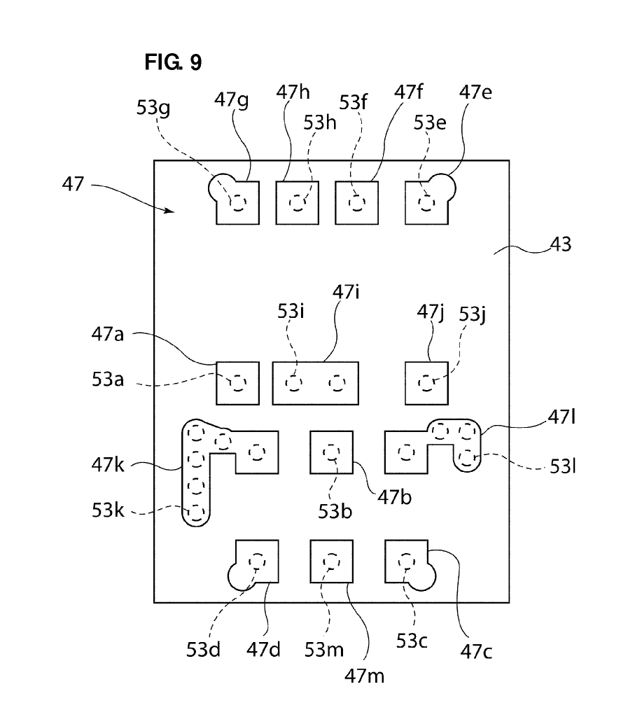

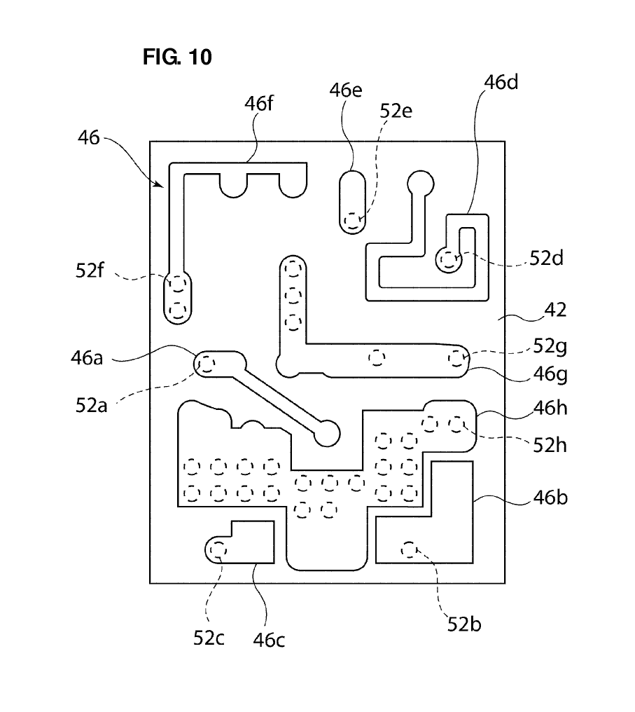

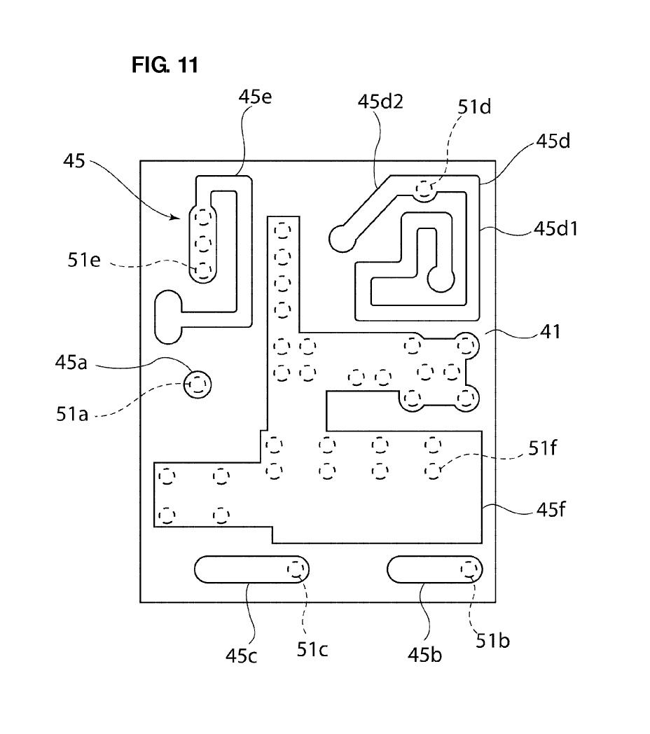

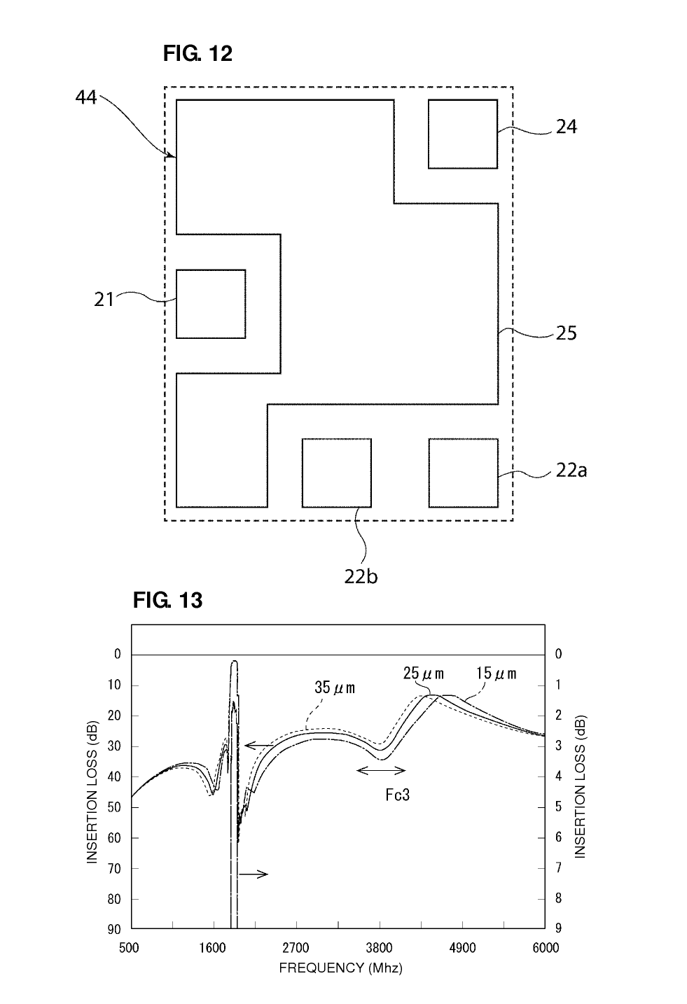

FIG. 8 is a schematic perspective plan view illustrating an overlapping state of the first electrode layer 44 and the second electrode layer 45 of the wiring board 18 in the duplexer according to the comparative example. FIG. 9 is a schematic perspective plan view of the fourth electrode layer 47 and the third dielectric layer 43 of the wiring board 18 in the duplexer according to the comparative example. FIG. 10 is a schematic perspective plan view of the third electrode layer 46 and the second dielectric layer 42 of the wiring board 18 in the duplexer according to the comparative example. FIG. 11 is a schematic perspective plan view of the second electrode layer 45 and the first dielectric layer 41 of the wiring board 18 in the duplexer according to the comparative example. FIG. 12 is a schematic perspective plan view of the first electrode layer 44 of the wiring board 18 in the duplexer according to the comparative example.

As illustrated in FIGS. 8 to 12, in the duplexer according to the comparative example, a portion of the electrode 45d (electrode portion 45d1) of the second electrode layer 45 defining the inductor L4 faces the ground terminal 25 of the first electrode layer 44 via the first dielectric layer 41. In the description of the comparative example, members substantially similar in function to those of the above-described preferred embodiment are denoted by similar reference signs, and description thereof will be omitted.

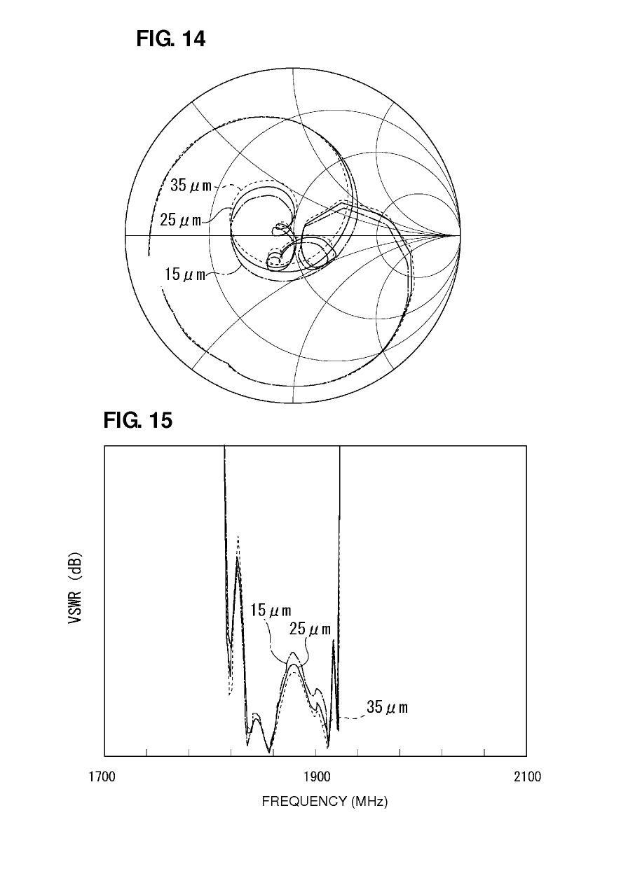

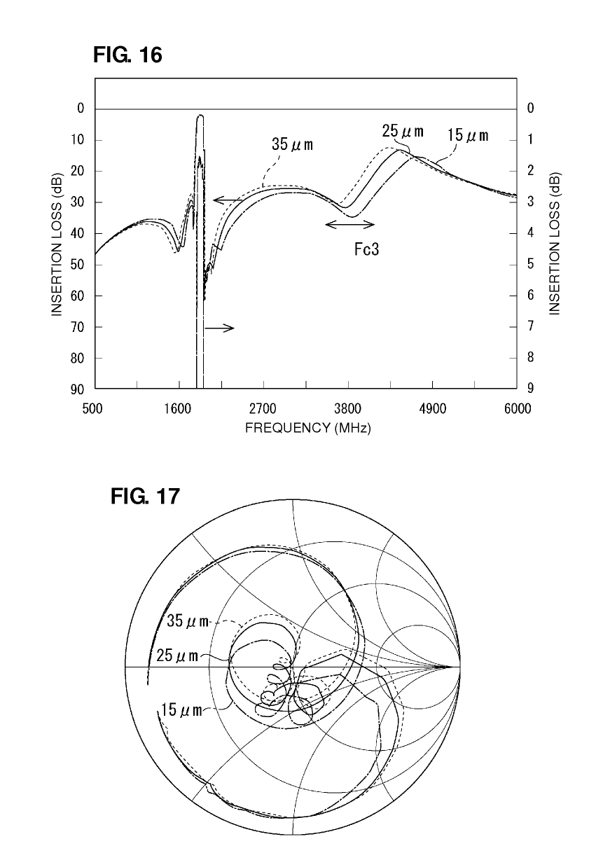

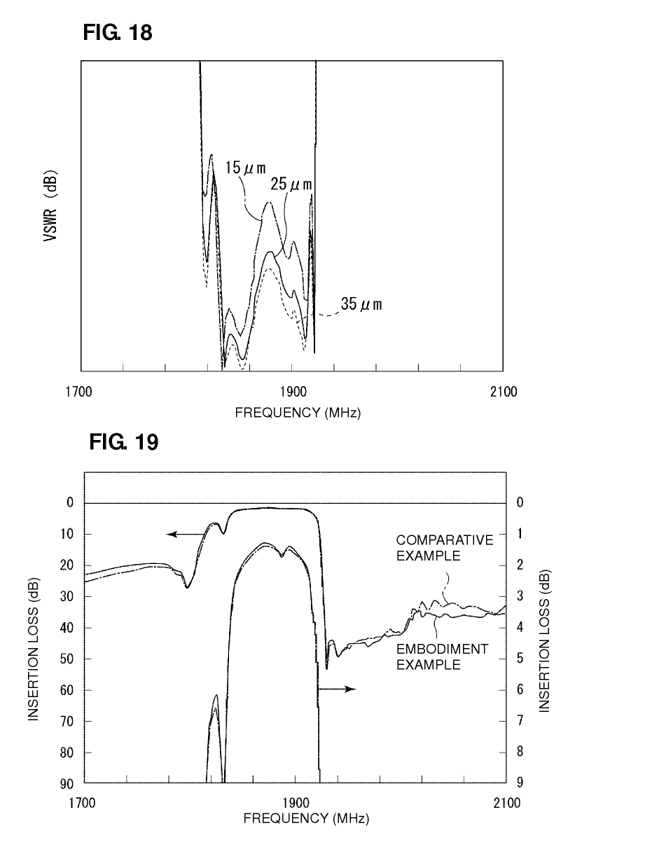

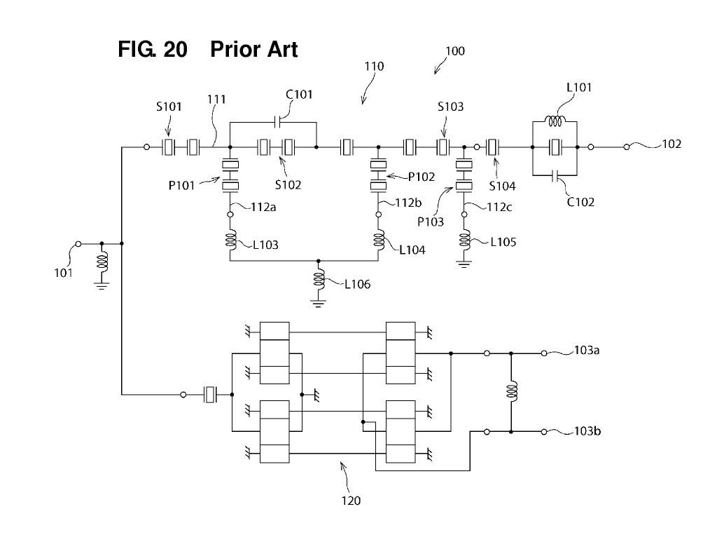

Herein, in each of the duplexer according to the example preferred embodiment of the present invention and the duplexer according to the comparative example, the filter characteristics were measured in cases where the thickness of the first dielectric layer 41 is 15 μm, 25 μm, and 35 μm, respectively. The thickness of the second dielectric layer 42 is 40 μm, and the thickness of the third dielectric layer 43 is 25 μm. FIG. 13 is graphs illustrating filter characteristics of the transmission filter 14 of the duplexer according to the example preferred embodiment of the present invention. FIG. 14 includes Smith charts at the transmitting terminal 24 of the duplexer according to the preferred embodiment example. FIG. 15 includes graphs illustrating VSWR (Voltage Standing Wave Ratio) characteristics of the transmission filter 14 of the duplexer according to the example preferred embodiment of the present invention. FIG. 16 includes graphs illustrating filter characteristics of the transmission filter 14 of the duplexer according to the comparative example. FIG. 17 includes Smith charts at the transmitting terminal 24 of the duplexer according to the comparative example. FIG. 18 includes graphs illustrating VSWR characteristics of the transmission filter 14 of the duplexer according to the comparative example. FIG. 19 includes graphs illustrating a filter characteristic of the transmission filter 14 of the duplexer according to the preferred embodiment example and a filter characteristic of the transmission filter 14 of the duplexer according to the comparative example in a case where the thickness of the first dielectric layer 41 is 25 μm.

In FIGS. 13 to 18, a graph or chart indicated as 15 μm is a graph or chart in the case where the thickness of the first dielectric layer 41 is 15 μm. In FIGS. 13 to 18, a graph or chart indicated as 25 μm is a graph or chart in the case where the thickness of the first dielectric layer 41 is 25 μm. In FIGS. 13 to 18, a graph or chart indicated as 35 μm is a graph or chart in the case where the thickness of the first dielectric layer 41 is 35 μm.

In FIGS. 13 and 16, FC3 represents an attenuation pole defined by the LC resonant circuit including the capacitor C1 and the inductor L4.

As is clear from FIGS. 13 and 16, the change in frequency position of the attenuation pole accompanying the change in thickness of the first to third dielectric layers 41 to 43 is smaller in the duplexer according to the example preferred embodiment of the present invention than in the duplexer according to the comparative example. If the change in frequency position of the attenuation pole accompanying the change in thickness of the first to third dielectric layers 41 to 43 is large, as in the duplexer according to the comparative example, a failure to properly attenuate the second harmonic signal may occur, depending on the manufacturing variation of the wiring board 18.

As shown in FIGS. 14 and 17, the variations in impedance matching at the transmitting terminal 24 are smaller in the duplexer according to the example preferred embodiment of the present invention than in the duplexer according to the comparative example. Further, as shown in FIGS. 15 and 18, the VSWR characteristic is more favorable in the duplexer according to the example preferred embodiment of the present invention than in the duplexer according to the comparative example.

As shown in FIG. 19, the insertion loss in the pass band is less in the duplexer according to the example preferred embodiment of the present invention than in the duplexer according to the comparative example.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave filter device comprising:
first and second signal terminals;
an inductor;
a ladder elastic wave filter unit connected between the first signal terminal and the second signal terminal;
an elastic wave filter chip provided with the ladder elastic wave filter unit; and
a wiring board including first and second main surfaces, and including the elastic wave filter chip mounted on the first main surface; wherein
the wiring board includes a plurality of dielectric layers and a plurality of electrode layers alternately laminated with one another;
an electrode layer of the plurality of electrode layers defining an uppermost layer includes a land electrode connected to the elastic wave filter chip;
an electrode layer of the plurality of electrode layers defining a lowermost layer includes a terminal defining the first signal terminal and a terminal defining the second signal terminal;
at least one electrode layer of the plurality of electrode layers includes an inductor electrode defining the inductor;
an electrode layer of the plurality of electrode layers disposed adjacent, via a dielectric layer of the plurality of dielectric layers, to the electrode layer including the inductor electrode includes a ground electrode connected to the ground; and
the inductor electrode and the ground electrode are arranged so as to not face each other via the dielectric layer.

2. The elastic wave filter device described in claim 1, wherein the inductor is connected in series between the first signal terminal and the second signal terminal.

3. The elastic wave filter device described in claim 1, wherein the ladder elastic wave filter unit includes a series arm defined by series arm resonators connected in series.

4. The elastic wave filter device described in claim 3, wherein the ladder elastic wave filter unit further includes parallel arms connected between the series arm and the ground.

5. The elastic wave filter device described in claim 1, wherein the second signal terminal is an antenna terminal.

6. The elastic wave filter device described in claim 5, further comprising a matching circuit connected between the ladder elastic wave filter unit and the second signal terminal, and the ground electrode.

7. The elastic wave filter device described in claim 6, wherein the matching circuit includes another inductor.

8. The elastic wave filter device described in claim 7, wherein the another inductor and the ground electrode are arranged so as to face each other via the dielectric layer.

9. The elastic wave filter device described in claim 1, further comprising a capacitor connected in parallel with the inductor electrode.

10. The elastic wave filter device described in claim 9, wherein the first signal terminal is a transmitting terminal.

11. The elastic wave filter device described in claim 10, wherein the capacitor and the inductor electrode are arranged to match an impedance at the first signal terminal.

12. The elastic wave filter device described in claim 1, further comprising a first receiving terminal and a second receiving terminal and a reception filter provided between the first receiving terminal and the second receiving terminal.

13. The elastic wave filter device described in claim 12, wherein the reception filter includes a plurality of longitudinally coupled resonator-type elastic wave filter units.

14. The elastic wave filter device described in claim 13, wherein the plurality of longitudinally coupled resonator-type elastic wave filter units include inter-digital transducer electrodes and reflectors.

15. The elastic wave filter device described in claim 12, wherein the reception filter includes an unbalanced signal terminal and first and second balanced signal terminals.

16. The elastic wave filter device described in claim 15, wherein the unbalanced signal terminal is connected to the first signal terminal, the first balanced signal terminal is connected to the first receiving terminal, and the second balanced signal terminal is connected to the second receiving terminal between the first receiving terminal and the second receiving terminal.

17. The elastic wave filter device described in claim 1, wherein the ladder elastic wave filter unit includes a plurality of resonators, the plurality of resonators including one inter-digital transducer electrode and one pair of reflectors disposed on opposite sides of the one inter-digital transducer electrode.

18. The elastic wave filter device described in claim 9, wherein the capacitor is provided by a pair of mutually interposed comb-shaped electrodes.

19. The elastic wave filter device described in claim 1, wherein the elastic wave filter chip is mounted on the wiring board through conductive bumps.

20. The elastic wave filter device described in claim 1, wherein the elastic wave filter chip is sealed with a sealing resin provided on the first main surface.
